(19) United States
(12) Patent Application Publication
(10) Pub. No.: US 2026/0187299 A1
(43) Pub. Date: Jul. 2, 2026

(54) INTELLIGENT OPERATION AND MAINTENANCE SYSTEM FOR FULL LIFE CYCLE OF LARGE-SCALE STEEL STRUCTURES

(71) Applicant: SHANDONG UNIVERSITY, Jinan (CN)

(72) Inventors: Shuhua GAO, Jinan (CN); Jing WANG, Jinan (CN); Zhengfang WANG, Jinan (CN); Yujie YANG, Jinan (CN); Xibei NI, Jinan (CN)

(21) Appl. No.: 19/432,987

(22) Filed: Dec. 25, 2025

(30) Foreign Application Priority Data
Dec. 27, 2024 (CN) 202411950102X

(51) Int. Cl. G06F 30/13; G06F 30/20; G06T 7/11; G06V 20/17

(52) U.S. Cl. CPC G06F 30/13; G06F 30/20; G06T 7/11; G06V 20/17; G06T 2207/10028; G06T 2207/10032

(57) ABSTRACT

An intelligent operation and maintenance system for full life cycle of a large-scale steel structure, may include: an intelligent identification and diagnosis module configured to acquire an inspection image captured by inspection equipment during the inspection process and to perform damage identification and localization based on a pre-trained damage identification model; a digital twin model construction module configured to construct a digital twin model and to perform online synchronization based on strain, temperature, or vibration distribution data acquired by a real-time data acquisition system; and a digital twin model visualization module configured to, in response to a visualization request, acquire a current digital twin model, and to synchronize all the damage identified based on the inspection image, as well as information on inspection equipment, welding equipment, and repair equipment in working conditions, to the digital twin model, and to perform visualization thereon.

### CROSS-REFERENCE TO RELATED APPLICATIONS

The present invention claims priority benefits to Chinese Patent Application No. 202411950102.X, entitled “INTELLIGENT OPERATION AND MAINTENANCE SYSTEM FOR FULL LIFE CYCLE OF LARGE-SCALE STEEL STRUCTURES”, filed on Dec. 27, 2024, with the China National Intellectual Property Administration, the entire content of which is incorporated herein by reference and constitutes a part of the present invention for all purposes.

### TECHNICAL FIELD

The present invention belongs to the technical field of operation and maintenance of large-scale steel structures, and particularly relates to an intelligent operation and maintenance system for full life cycle of a large-scale steel structure.

### BACKGROUND

The statement in this section merely provides the background art information related to the present invention and does not necessarily constitute the prior art.

Large-scale steel structures are featured by irregular component shapes, complex interconnections among numerous rod members, and overlapping obstructions. Single automated inspection equipment is difficult to achieve comprehensive coverage of the field of view. For example, unmanned aerial vehicles (UAVs) and ground inspection robots are difficult to adequately address internal rod members with obstructions. Especially, since many steel structures have external enclosures and internal ceilings, these equipments are inapplicable to these steel structures fundamentally. Therefore, inspection of large-scale steel structures still primarily relies on manual methods; manual methods require working at heights, posing significant risks. Meanwhile, manual inspection typically depends on the experience of operation and maintenance personnel. The operation and maintenance personnel only use detection equipments to inspect a certain location when they subjectively judge that damage may exist in the location, leading to missed detections. Furthermore, operating personnel cannot reach confined spaces, and comprehensive coverage of inspection cannot be thus achieved. Moreover, the manual methods place high demands on the professional knowledge of operation and maintenance personnel. Operation and maintenance personnel need to be familiar with the mechanisms of action from various loads on steel structures, and familiar with the applicability of different detection tools. The above current situations cause challenges to the operation and maintenance of complex large-scale steel structures, including one-sidedness, static monitoring, passivity, and blindness.

### SUMMARY

To overcome the deficiencies of the prior art described above, the present invention provides an intelligent operation and maintenance system for full life cycle of a large-scale steel structure. On the basis of achieving online synchronization of a digital twin model and by superimposing damage identification and analysis results obtained from inspection images, the system may remotely display the real-time status of the large-scale steel structure to operation and maintenance personnel more intuitively.

To achieve the above objectives, one or more examples of the present invention provide an intelligent operation and maintenance system for full life cycle of a large-scale steel structure, including a real-time data acquisition system, inspection equipment, welding equipment, repair equipment, and an integrated platform. The integrated platform is configured to include:
a collaborative control module, configured to collaboratively control the inspection equipment, the welding equipment, and the repair equipment;
an equipment status monitoring module, configured to acquire real-time positioning of the inspection equipment, the welding equipment, and the repair equipment;
an intelligent identification and diagnosis module, configured to acquire an inspection image captured by the inspection equipment during an inspection process, and to perform a damage identification and positioning on the inspection image based on a pre-trained damage identification model;
a digital twin model construction module, configured to construct a digital twin model and to perform online synchronization based on strain, temperature, or vibration distribution data acquired by the real-time data acquisition system; and
a digital twin model visualization module, configured to, in response to a visualization request, acquire a current digital twin model, and synchronize damages identified based on the inspection image, as well as information on the inspection equipment, the welding equipment, and the repair equipment in working conditions, to the current digital twin model, and to perform visualization.

In some embodiments, the inspection equipment includes at least one unmanned aerial vehicle (UAV) and at least one wall-climbing robot; and a method of planning inspection paths based on the at least one UAV and the at least one wall-climbing robot includes:
acquiring three-dimensional (3D) point cloud data of the large-scale steel structure, determining a set of point clouds capable of falling within a field of view of the at least one UAV according to a given flight altitude and a given field of view of the at least one UAV, thereby obtaining an inspection range of the at least one UAV; and, the set of point clouds beyond the inspection range of the at least one UAV is defined as an inspection range of the at least one wall-climbing robot; and
planning the inspection paths for the at least one UAV and the at least one wall-climbing robot, respectively within the inspection ranges of the at least one UAV and the at least one wall-climbing robot.

In some embodiments, planning the inspection path for the at least one UAV within the inspection range of the at least one UAV includes:
extracting outer layer data according to the point cloud data within the inspection range of the at least one UAV and expanding a set distance outward, and fitting to obtain an inspection flight plane of the at least one UAV;
clustering the 3D point cloud data of the large-scale steel structure within the inspection range of the at least UAV to obtain point cloud data of a plurality of steel segments; extracting a centerline according to the point cloud data of each of the plurality of the steel segments to obtain a centerline spatial network; performing a 3D grid division on the centerline spatial network, and extracting a detection viewpoint for each grid traversed by the centerline; and
clustering all intersection points according to a set distance threshold to obtain a plurality of intersection point clusters, and taking a center of each of the plurality of the intersection point clusters as a fixed inspection point position for the at least one UAV.

In some embodiments, planning the inspection path for the at least one wall-climbing robot within the inspection range of the at least one wall-climbing robot includes:
constructing a spatial coordinate system with a set position as an origin to obtain coordinate information of the point cloud data; and obtaining boundary coordinate information of the inspection range of the at least one wall-climbing robot according to the inspection range of the at least one wall-climbing robot;
dividing the 3D point cloud data of the large-scale steel structure within the boundary range into the steel segments, projecting all the steel segments onto a set two-dimensional (2D) plane, and calculating a projection matrix; extracting a detection viewpoint from each of the projected steel segments by grid sampling, and calculating line-of-sight (LOS) directions corresponding to all the detection viewpoints based on a plane normal vector feature; and
restoring all the detection viewpoints and the LOS directions to a 3D space according to the projection matrix, acquiring intersection points of all the LOS directions with a nearest steel segment, and determining the steel segments where these intersection points are located; designating the steel segments after the determination as steel segments to be climbed, and designating the intersection points after the determination as fixed inspection point positions for the at least one wall-climbing robot.

In some embodiments, a method of constructing the digital twin model includes:
constructing an in-service steel structure geometric model based on multi-view point cloud data and a design drawing;
acquiring multi-source heterogeneous data reflecting a health status of the steel structure;
performing cross-modal fusion on the multi-source heterogeneous data to obtain a cross-modal fusion feature, specifically including:
obtaining a strain and temperature feature mapping and a vibration feature mapping based on the multi-source heterogeneous data of the steel structure;
calculating a characterization value of information of the strain and temperature feature mapping at any position as a univariate function;
calculating a correlation between the information of the strain and temperature feature mapping at any position and information of the vibration feature mapping at any position in a form of an embedded Gaussian function as a bivariate function;
performing cross-modal fusion based on the univariate function and the bivariate function to obtain a cross-modal fusion feature;
constructing the digital twin model corresponding to the steel structure geometric model by combining steel structure geometric model data with the cross-modal fusion feature data; and
performing dynamic prediction and correction on the constructed digital twin model to obtain a corrected digital twin model.

In some embodiments, the formula for performing cross-modal fusion based on the univariate function and the bivariate function to obtain a cross-modal fusion feature is as follows:

$${y}_{i} = \frac{{\sum }_{∀ j} P ( {f}_{2 i} , {f}_{1 j} ) g ( {f}_{1 j} )}{{\sum }_{∀ j} P ( {f}_{2 i} , {f}_{1 j} )} ;$$

wherein, the univariate function g(·) serves to calculate the characterization value of the information f₁ⱼ of the feature mapping F₁ at position j; the bivariate function P serves to calculate the correlation between the information f₁ⱼ of feature mapping F₁ at position j and the information f₂ᵢ of feature mapping F₂ at position i in the form of an embedded Gaussian function.

In some embodiments, constructing the digital twin model corresponding to a steel structure geometric model by combining steel structure geometric model data with the cross-modal fusion feature data includes:
aligning the steel structure geometric model data and the cross-modal fusion feature data in both temporal and spatial dimensions;
training an inference model based on the aligned steel structure geometric model data and fusion feature data before and after parameter changing of the steel structure to obtain a trained inference model; and
in combination with real-time monitored multi-source heterogeneous data reflecting the health status of the steel structure and a finite element simulation analysis result, mapping the monitoring data to the 3D model by the trained inference model, to complete the construction of the digital twin model.

In some embodiments, the performing dynamic prediction and correction on the constructed digital twin model to obtain a corrected digital twin model is based on selecting different weights for multi-source data fusion according to the differences in influences of multi-source data on different nodes, so as to minimize a sum of squared Euclidean distances between the fusion result and each data.

In some embodiments, the operation and maintenance system further comprises a damage alarm module, configured to issue alarm information upon identifying damage, and the alarm information comprises a damage image, and location information of a steel segment where the damage is located.

In some embodiments, the operation and maintenance system further comprises an intelligent repair module, configured to control a repair robot and a welding robot to autonomously repair the steel structure based on the location, type, and degree of the damage.

In one or more of the above technical solutions, the strain, temperature, or vibration distribution data and the inspection image data are acquired, respectively. On the basis of achieving online synchronization of the digital twin model and by superimposing damage identification and analysis results obtained from the inspection images, the system may remotely display the real-time status of the large-scale steel structure to operation and maintenance personnel more intuitively.

### BRIEF DESCRIPTION OF THE DRAWINGS

Drawings attached to the description that constitute a part of the present invention are used to provide a further understanding of the present invention. Schematic examples of the present invention and specification thereof are used to interpret the present invention and are free of constituting improper limitations to the present invention.

FIG. 1 is a functional framework diagram of the intelligent operation and maintenance system for full life cycle of a large-scale steel structure according to an example of the present invention;

FIG. 2 is an overall flow chart of a path planning method according to an example of the present invention;

FIG. 3 is a schematic diagram showing a principle of UAV path planning according to an example of the present invention;

FIG. 4 is a flow chart of a method for constructing a digital twin model of a large-scale steel structure fused with multi-source data according to an example of the present invention;

FIG. 5 is a schematic diagram showing a real-time data acquisition system provided in an example of the present invention; and

FIG. 6 is a schematic diagram showing a cross-modal fusion feature provided in an example of the present invention.

### DETAILED DESCRIPTION

The examples of the present application will be described below more specifically with reference to the accompanying drawings. Although certain examples of the present application are shown in the accompanying drawings, it should be understood that the present application may be implemented in various forms and should not be construed as limiting the examples set forth herein. Rather, these examples are provided so that the present application will be understood thoroughly and completely. It should be understood that the accompanying drawings and examples of the present application are merely provided for exemplary purposes but are not intended to limit the scope of protection of the present application.

In the description of the examples of the present application, the term “include” and its variants should be understood as open-ended inclusion, that is, “including but not limited to.” The term “based on” should be understood as “at least partially based on.”

Directed to the existing problems in the operation and maintenance of large-scale steel structures, one or more examples of the present invention provide an intelligent operation and maintenance system for full life cycle of a large-scale steel structure, including a real-time data acquisition system, inspection equipment, welding equipment, repair equipment, an integrated platform, and a client. The real-time data acquisition system, the inspection equipment, welding equipment, and the repair equipment are all connected to the integrated platform, and the client may establish a communication connection with the integrated platform to access the integrated platform.

The real-time data acquisition system acquires real-time monitoring data using a steel structure key-parameter monitoring system based on distributed optical fiber sensing. The system includes a pulse light generator, a circulator, a wavelength division multiplexer, two photoelectric detectors, sensing optical fiber, and a computer. The computer sends control signals to the pulse light generator and photoelectric detectors and simultaneously starts signal acquisition through three channels. The pulse light generator emits pulsed light, then the pulsed light passes through the circulator and wavelength division multiplexer to reach the sensing optical fiber arranged at a set position on the surface of the steel structure. The backward Rayleigh reflected light is collected by the first photoelectric detector via the wavelength division multiplexer and circulator. The backscattered Brillouin light includes Stokes light and anti-Stokes light. Due to their different wavelengths, the Stokes light and anti-Stokes light are collected by the second photoelectric detector via the wavelength division multiplexer. Afterwards, the second photoelectric detector converts the collected reflected light signals into electric signals and transmits them to the main control computer for analysis, thereby obtaining the current strain, temperature, or vibration distribution on the surface of the steel structure and acquiring the multi-source heterogeneous data reflecting the health condition of the steel structure.

As an example, as shown in FIG. 5, when the system operates normally, the main control computer sends control signals to the pulse light generator and the photoelectric detectors (APD1, APD2) and simultaneously acquires signals through three channels (channel 1, channel 2, and channel 3) via a data acquisition card. The pulse light generator emits infrared pulsed light having a central wavelength of a C band; then the infrared pulsed light passes through the circulator and the wavelength division multiplexer to reach the sensing optical fiber arranged at a set position on the surface of the steel structure. Changes in external stress, temperature, or vibration cause changes in the scattering information of the pulsed light in the sensing optical fiber. Hence, the system mainly collects backward Rayleigh scattered light and two circuits of backward Brillouin scattered light. The backward Rayleigh reflected light is collected by the photoelectric detector APD1 after through the wavelength division multiplexer and the circulator. The Stokes light and anti-Stokes light in the backscattered Brillouin light are collected by the photoelectric detector APD2 after through the wavelength division multiplexer, respectively. After being collected, the reflected optical signal is converted by the photoelectric detector into an electric signal and then transmitted to the main control computer. The main control computer performs signal preprocessing such as denoising and decoupling on the collected signal, and then generates the corresponding strain, temperature, or vibration curve, thereby obtaining the current strain, temperature, or vibration distribution on the surface of the steel structure.

When the system monitors an abnormal strain, temperature, or vibration at a certain location, the position of the damage in the steel structure may be determined through signal decoupling analysis. Furthermore, by analyzing the intensity of the scattering signal, it may be determined whether the optical fiber arranged on the surface of the steel structure is broken or bent, thereby ensuring the reliability of the acquired data.

The inspection equipment is configured to:
perform patrol inspection based on a predetermined inspection path, and transmit fixed-point inspection images back to the integrated platform during the inspection process.

To reduce data transmission pressure, the inspection equipment may be internally provided with a preliminary defect discrimination model to preliminarily screen the images captured during the inspection process, excluding normal images; suspected defect images are only transmitted to the integrated platform. As an example, images of defect-free and defective steel segments are used to train a binary classification model based on a support vector machine (SVM), which only distinguishes the presence or absence of a defect. Images of steel segments determined to have defects are treated as suspected defect images and transmitted to the integrated platform.

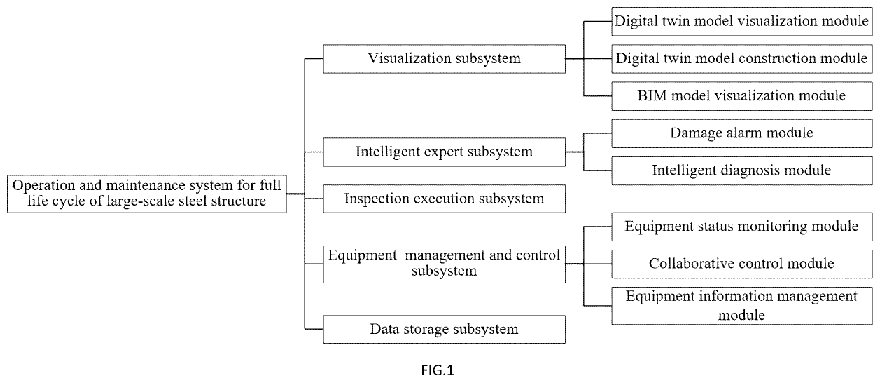

As shown in FIG. 1, the integrated platform is configured to:
a data storage subsystem, configured to acquire each fixed-point inspection image as well as the strain, temperature, or vibration distribution on the surface of the steel structure at each moment, and store them. On this basis, the inspection images during the full life cycle may be obtained for each fixed inspection point. It is understood that, to ensure transparency and traceability at each stage, technologies such as blockchain, access passwords, and digital digests may be adopted, in combination with full life cycle information in the cloud, to construct a full-chain information traceability mechanism. This facilitates analysis of the evolution mechanism of different types of damage in large-scale steel structures, which provides a data foundation for the construction of a damage identification inversion model for large-scale steel structures.

An equipment management and control subsystem is configured to include:
an equipment information management module, configured to manage information on the inspection equipment, the welding equipment, and the repair equipment, where the inspection equipment includes one or more wall-climbing robots, and/or one or more UAVs, the welding equipment may be a welding robot, and the repair equipment may be a wall-climbing corrosion repair robot, which will be defined herein specifically;
a collaborative control module, configured to collaboratively control the inspection equipment, the welding equipment, and the repair equipment; and
an equipment status monitoring module, configured to acquire real-time positioning and real-time operating parameters of the inspection equipment, the welding equipment, and the repair equipment, to determine whether these equipments are operating normally and whether they are operating along the specified paths.

An inspection execution subsystem is configured to include:
an inspection path planning module, configured to plan inspection paths for one or more inspection devices for large-scale steel structures, so as to obtain the inspection path for each inspection device.

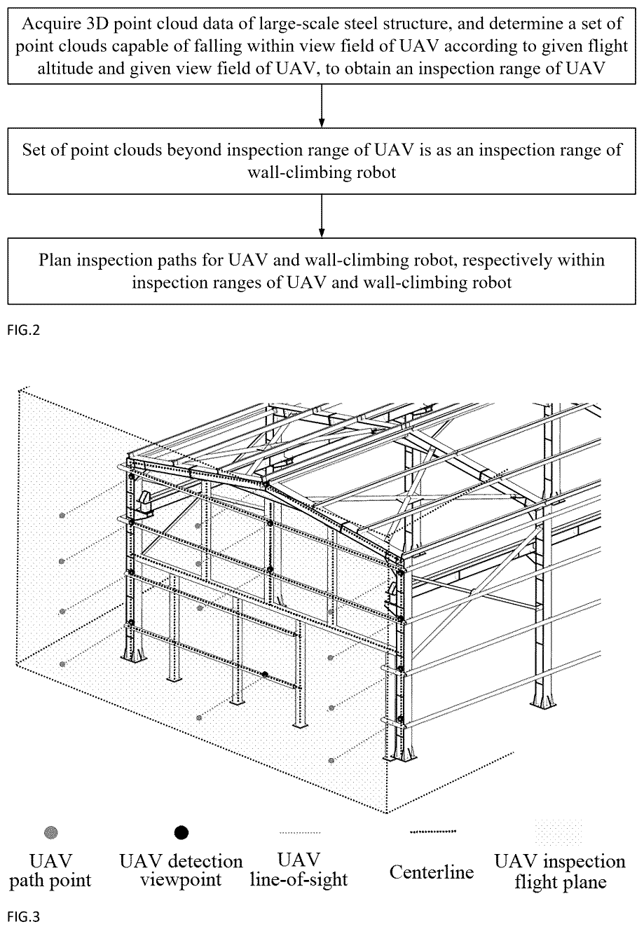

As a detailed example, the inspection equipment includes two types: UAVs and wall-climbing robots. An aerial-ground cooperative inspection path planning method is adopted, as shown in FIG. 2. The method specifically includes:
step 1: acquiring 3D point cloud data of the large-scale steel structure, determining a set of point clouds capable of falling within a field of view of the UAV according to a given flight altitude and a given field of view of an UAV, thereby obtaining an inspection range of the UAV; and a set of point clouds beyond the inspection range of the UAV is an inspection range of a wall-climbing robot; and
step 2: planning inspection paths for the UAV and the wall-climbing robot, respectively within the inspection ranges of the UAV and the wall-climbing robot.

In step 1, a spatial coordinate system is first constructed with a set position as the origin to obtain the coordinate information of the point cloud data. As an example, the ground center point of the steel structure building may be used as the origin. The inspection range of the UAV is mainly analyzed based on the UAV performance parameters such as the detection accuracy and the monitoring range. The flight altitude of the UAV is the maximum distance between the UAV and the steel structure and is correlated to the resolution ratio of the onboard vision system. Within the maximum flight altitude of the UAV, it is subjected to the altitude at which defects of a given size may be clearly photographed. The field of view is correlated to the field of view of the vision system and the degree of freedom (DOF) of the gimbal. When the parameters of the UAV, the gimbal on the UAV and vision system thereon are determined, the flight altitude and field of view may be obtained by calculation.

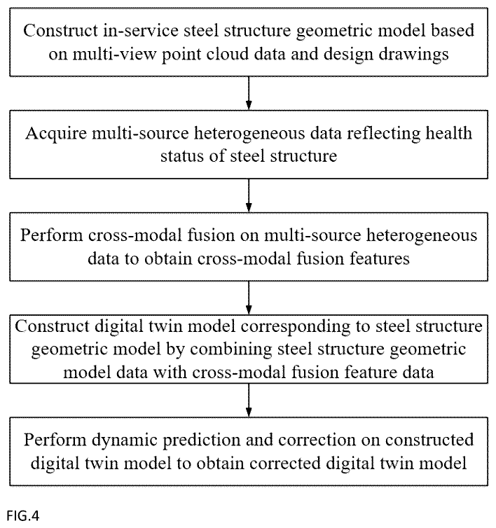

In step 2, as shown in FIG. 3, the inspection path planning for the UAV within the inspection range of the UAV specifically includes the followings:
(1) extracting outer layer data according to the point cloud data within the inspection range of the UAV and a set distance is expanded outward to fit the inspection flight plane of the UAV; the set distance is the distance between the UAV and the steel structure during inspection. It is understood that, when the ground center point of the steel structure building is used as the origin, the points farthest from the origin of coordinates in the same ray direction with the origin of coordinates as the starting point are denoted as the outer layer data.
(2) clustering the steel structure point cloud data within the inspection range of the UAV to obtain point cloud data of a plurality of steel segments, a centerline is extracted according to the point cloud data of each steel segment to obtain a centerline spatial network; the centerline spatial network is subjected to 3D grid (cubic grid) division, and a detection viewpoint is extracted for each grid traversed by a centerline.
(3) For each detection viewpoint, calculating the intersection point where the distance to the UAV inspection flight plane is minimized, and designating the direction from the detection viewpoint to this intersection point as the LOS direction.
(4) clustering all the intersection points according to a set distance threshold to obtain a plurality of intersection point clusters, and a center of each intersection point cluster serves as a fixed inspection point position for the UAV. The UAV photographs the corresponding viewpoint at the fixed point position.
(5) planning a minimized path according to all the fixed inspection point positions of the UAV.

The centerline within the inspection range is extracted and subjected to 3D grid division, and a viewpoint is extracted within each 3D grid. Such a configuration ensures that during the subsequent UAV detection, the field of view may cover all the steel structure segments within the inspection range, thereby avoiding missed viewing angles or undetected defects.

After obtaining all the fixed inspection point positions for the UAV, these fixed inspection point positions are subjected path planning to organize into a coherent path. As an example, an ant colony algorithm may be used for path planning.

Since the wall-climbing robot is attached to the surface of the steel structure for operation, the detection field of view is limited. To balance work efficiency and energy saving, it is necessary to ensure that the field of view of the wall-climbing robot may cover the entire inspection ranges while minimizing the crawling path length.

Based on this, the planning on the inspection path of the wall-climbing robot within its inspection range specifically includes the followings:
(1) clustering the steel structure point cloud data within the inspection range of the wall-climbing robot to obtain point cloud data of a plurality of steel segments, extracting a centerline according to the point cloud data of each steel segment to obtain a centerline spatial network; the centerline spatial network is subjected to 3D grid (cubic grid) division, and a detection viewpoint is extracted for each grid traversed by a centerline.
(2) For each detection viewpoint, determining a plurality of steel segments that are visible from the detection viewpoint. That is, for each detection viewpoint, a set of steel segments that are visible from the viewpoint may be obtained. These sets of steel segments are analyzed, and the steel segment with the most visible viewpoints is selected preferably. The minimum number of steel segments is targeted to obtain the corresponding steel segment for each viewpoint.
(3) designating these steel segments as steel segments to be climbed, and designating the intersection points from the detection viewpoints to the corresponding steel segments as the fixed inspection point positions for the wall-climbing robot, which is used to photograph the viewpoints along the corresponding lines of sight.
(4) performing the planning of the minimized path based on the steel segments to be climbed and the fixed inspection point positions on each steel segment. It is understood that the minimized path is a coherent path that covers all the steel segments to be climbed and the fixed inspection point positions on each steel segment.

Since the wall-climbing robot is required to traverse all the steel segments to be climbed and repeated traversal of steel segments is allowed, the above path planning problem may be equivalently transformed into an arc routing problem. That is, it is required to find one minimized path such that each steel segment to be climbed in the steel structure is traversed at least once. As an example, the following method may be adopted: an undirected road network graph is established based on all the steel segments to be climbed. The endpoints of each steel segment serve as nodes of the graph, each steel segment serves as the edge connecting two nodes, and the length of each steel segment determines the weight of the edge. The path planning is performed using the existing solutions for solving problems under large-scale road network.

The path is solved based on the above method, and all the fixed inspection point positions within each steel segment are smoothly connected to generate the final path.

On this basis, the division of inspection ranges and inspection path planning for the UAV and wall-climbing robot are achieved. For large-scale steel structures, a single UAV and a single wall-climbing robot may not meet daily inspection requirements due to limitations such as cruising power. Multiple equipments may be required for coordination to achieve the objective.

Based on this, for large-scale steel structures, the present invention further includes:
Step 3: According to the performance parameters of the UAV and the wall-climbing robot, whether a single equipment may complete the inspection task is determined; if not, the number of the UAVs required and the number of the wall-climbing robots required are further calculated, and the inspection paths are allocated accordingly.

Viewpoints are extracted based on the point cloud data to ensure the comprehensiveness of the subsequent inspection viewpoints. Furthermore, the lines of sight are clustered to determine the fixed inspection point positions during the inspection process, which may enable the inspection equipment to photograph a larger range on a fixed inspection point position while ensuring the comprehensive coverage of the inspection field of view. Hence, when areas with dense steel segments are photographed, the inspection equipment may increase dwell times at the point position to ensure high-density coverage.

An intelligent expert subsystem is configured to include:

An intelligent identification and diagnosis module, configured to perform damage identification based on the inspection images and a pre-trained damage identification model. As an example, the damage identification model may be obtained by training an existing neural network model to achieve accurate localization of corrosion, feature identification and area calculation, bolt loosening identification, and pixel-level extraction of weld seam cracking.

A damage alarm module, configured to issue alarm information upon identifying damage, and the alarm information includes damage image and location information of a steel segment where the damage is located.

An intelligent repair module, configured to control a repair robot and a welding robot to autonomously repair the steel structure based on the location, type, and degree of the damage.

A visualization subsystem is configured to include:
a building information modeling (BIM) model visualization module, configured to visualize a BIM design model of the large-scale steel structure;
a digital twin model construction module, configured for online synchronization of the digital twin model; and
a digital twin model visualization module, configured to acquire the damage identified based on the inspection images and, according to the location and size of the damage, synchronize the damage to the digital twin model and to visualize the damage.

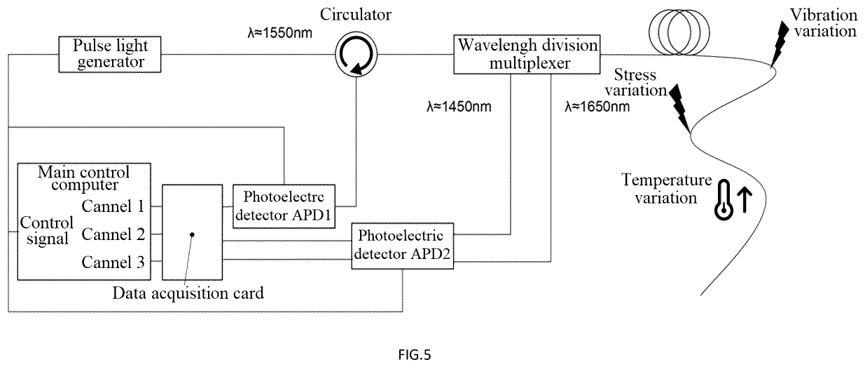

As shown in FIG. 4, the method for constructing the digital twin model includes the following steps:
step 1: constructing an in-service steel structure geometric model based on multi-view point cloud data and a design drawing;
step 2: acquiring multi-source heterogeneous data reflecting a health status of the steel structure;
step 3: performing cross-modal fusion on the multi-source heterogeneous data to obtain a cross-modal fusion feature;
step 4: constructing the digital twin model corresponding to a steel structure geometric model by combining steel structure geometric model data with the cross-modal fusion feature data; and
step 5: performing dynamic prediction and correction on the constructed digital twin model to obtain a corrected digital twin model.

The step 1 specifically includes:
constructing a 3D model of the in-service steel structure based on the acquired multi-view point cloud data;
constructing the BIM design model of the in-service steel structure based on the design drawings; and
comparing the 3D model to the BIM design model of the in-service steel structure, matching the feature point matrix of the 3D point cloud model of the steel members, and obtaining the geometric 3D model of the steel structure.

During on-site construction, in view of geometric deviations, shape differences and other problems existing between the BIM design model and the on-site steel members, quality monitoring of steel members may be achieved by comparing the BIM design model with the 3D reconstructed model of the steel structure scanned on site. It is appreciable to those skilled in the art that the above construction methods of 3D model based on the point cloud data and design drawings may be implemented using existing methods, which will be thus defined herein specifically.

In step 2, after the acquiring multi-source heterogeneous data reflecting a health status of the steel structure, performing data preprocessing includes: denoising the multi-source heterogeneous data based on a constructed denoising autoencoder, and normalizing the denoised multi-source heterogeneous data. The multi-source heterogeneous data is the structured data mainly consisting of dynamic time-series data. Dynamic correction of the existing erroneous data is completed by performing data cleaning operations such as duplicate data deletion and complementing missing data on the multi-source data. Directed to the problems of signal noise interference and reduced signal confidence in the system-acquired signals, a denoising autoencoder network is designed using methods such as wavelet denoising and adaptive filtering to perform denoising preprocessing on the acquired data.

The multi-source heterogeneous data acquired in the operation and maintenance of large-scale steel structures contains a large amount of information. How to extract the key features from the heterogeneous multi-source information, filter redundant information, and to achieve the deep fusion of multi-source data with 3D models is a problem to be solved urgently in the fusion of the digital twin model with the multi-source heterogeneous data. In step 3, a feature extraction method based on a pre-trained model is adopted such that useful feature information is more concerned by the network to the dynamic data, thus improving its ability to suppress redundant information. Then, different modal data is processed comprehensively by a feature fusion technology, and a cross-modal attention mechanism is introduced to further enable feature interaction among multi-source heterogeneous data, thereby enhancing data fusion effect and providing more comprehensive, accurate, and reliable information. Step 3 specifically includes:
the strain, temperature, and vibration time-series data of the distributed optical fiber collected by the multi-source heterogeneous data monitoring platform are input into the pre-trained model to obtain the strain and temperature feature mapping F₁ and the vibration feature mapping F₂. In this example, the pre-trained model may employ a deep neural network (e.g., a convolutional neural network, CNN, or a recurrent neural network, RNN) as the basic architecture, and trains features learned from a large amount of labeled data, thus performing effective feature extraction on the input data. The feature extraction method based on a pre-trained model is adopted such that the network concerns useful feature information on the dynamic monitoring data of the distributed optical fiber more concerned, thus improving its ability to suppress redundant information.

Then, different modal data is processed comprehensively by a feature fusion technology, and a cross-modal attention mechanism is introduced to further enable feature interaction among multi-source heterogeneous data, thereby enhancing data fusion effect and providing more comprehensive, accurate, and reliable information.

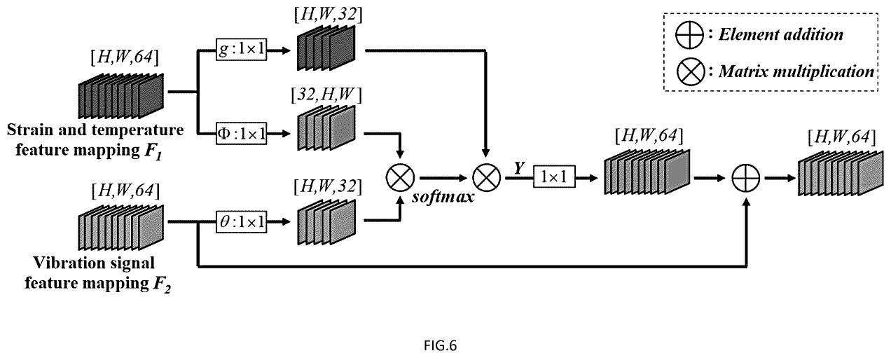

FIG. 6 is a structural diagram showing the cross-modal cross-attention module, where the two inputs of the module are the strain and temperature feature mapping F₁ and the vibration feature mapping F₂ extracted by the neural network. The cross-modal cross-attention module may be defined as follows:

$${y}_{i} = \frac{{\sum }_{∀ j} P ( {f}_{2 i} , {f}_{1 j} ) g ( {f}_{1 j} )}{{\sum }_{∀ j} P ( {f}_{2 i} , {f}_{1 j} )} ;$$

wherein, yᵢ is the result of normalized weighted summation of the features at all positions of F₁ and the feature F₂ at position i; i is the index of a certain position in F₂; j is the index of a certain position in F₁. The univariate function g is used to calculate the representative value of the information f₁ⱼ at position j of the feature mapping F₁, which is usually calculated by linear weighting as follows: g(f₁ⱼ)=W_{g}f₁ⱼ, wherein W_{g}, as a weight parameter, is optimized during model training, and may be implemented by a 1×1 convolution operation in practical computation.

In addition, in this example, the bivariate function P is used to calculate the correlation between the information f₁ⱼ at position j of feature mapping F₁ and the information f₂ᵢ at position i of feature mapping F₂ in the form of an embedded Gaussian function. The expression of the bivariate function P is as follows:

$$P ( {f}_{2 i} , {f}_{1 j} ) = {e}^{{θ ( {f}_{2 i} )}^{T} {Φ ( {f}_{1 j} )}_{;}}$$

wherein, θ(f₂ᵢ) and φ(f₁ⱼ), as two embedding options, are calculated by the following process:

$$θ ( {f}_{2 i} ) = {W}_{θ} {f}_{2 i} ;$$

$$Φ ( {f}_{1 j} ) = {W}_{Φ} {f}_{1 j} ;$$

wherein, the weight matrices W_{θ} and W_{φ} are optimized using a 1×1 convolution operation.

Finally, the cross-modal fusion feature Z output by the cross-modal cross-attention module is obtained by element-wise addition of the feature mapping F₂ and yᵢ:

$${z}_{i} = {W}_{z} {y}_{i} + {f}_{2 i} ;$$

wherein, W_{z} as a weight matrix to be trained, may be also implemented using a 1×1 convolution operation.

Step 4 specifically includes the following steps:

First, to ensure accurate mapping and consistency of the data, methods such as resampling and temporal alignment are used to achieve synchronization and alignment of the multi-source heterogeneous data and the 3D model in both temporal and spatial dimensions.

The inference model is trained to obtain the trained neural network inference model based on the multi-view point cloud data and the fusion features of the multi-source heterogeneous data reflecting health data of the steel structure before and after parameter changing;
denoted as:

$${S}_{0} , {C}_{0} , {C}_{t} ∈ {M}_{1}^{d} , {M}_{2}^{d} , … , {M}_{n}^{d} ;$$

$${S}_{t} = N N ( {S}_{0} , {C}_{0} , {C}_{t} )$$

wherein, S₀ represents the reconstructed geometric model of the steel structure, C₀ represents the data fusion feature before the key parameter change of the steel structure, Cₜ represents the data fusion feature after the key parameter change of the steel structure at time t, Sₜ represents the mapping relationship between a multi-source data monitoring field and a reconstructed model deformation field at time t, NN represents the neural network inference model, and

$${M}_{t}^{d}$$

represents the monitoring data at time t.

By utilizing multi-physical quantity information such as temperature, stress, and vibration collected in real time by the distributed optical fiber monitoring technology, and combined with the result of the finite element simulation analysis, the data is mapped and inferred by the trained inference model, thereby achieving accurate mapping from the monitoring data to the 3D model. That is, the construction of the digital twin model is completed.

The monitoring results under the current monitoring state are compared with the mapping results. The accuracy and reliability of the digital twin inference model are verified by the difference between the measured monitoring data and the mapping results.

$$V = \overline{\sum {V}^{3} ⋂ {V}_{p}^{3}} ;$$

V denotes the average verification result, V³ denotes the measured data, and

$${V}_{p}^{3}$$

denotes the model mapping result.

To further improve the accuracy of the digital twin model, a dynamic prediction and correction method for the digital twin model based on multi-source data fusion is put forward. For the differences in the influence of the multi-source data on different nodes, different weights are selected for multi-source data fusion, so as to achieve the purpose of minimizing a quadratic sum of Euclidean distances between the fusion result and each data. The calculation formula is:

$${E}_{k} = {\sum }_{i = 1}^{N} {W}^{i} * cat ( \vec{{H}_{k}^{ι}} , \overleftarrow{{H}_{k}^{ι}} ) + {b}^{i} ;$$

wherein, cat

$$( \vec{{H}_{k}^{ι}} , \overleftarrow{{H}_{k}^{ι}} )$$

is the spatial context information of the i^{th} data source at time k; Wⁱ is the weight of the i^{th} data source, which is configured according to its influence on the steel structure. bⁱ is the bias term of the i^{th} data source, which is configured to adjust the fusion result and may serve as a part of the network optimization parameters.

The digital twin model is corrected by combining the fused data with the simulation data of the finite element model, ensuring a high fidelity of the digital twin model. A generative decoder is used to predict the distributed optical fiber monitoring data at the current moment and directly output multi-step prediction results; specifically including the following steps:

The collected steel structure monitoring data are used as a “start character”. The data to be predicted are all initialized to zero and input into the decoder as input data. The trained decoder predicts the decoder input data, and the prediction results are put into the predictive content and output.

The entire decoding process of the decoder abandons the dynamic decoding process and instead adopts a single forward process, to decode the entire output sequence.

In addition, during training, MSE is selected as a loss function, and the entire predictive content is subjected to loss calculation to obtain the final prediction result. The output dimension of the fully connected layer depends on the dimension of the variables to be predicted.

It should be noted that the original prediction method is point-by-point dynamic decoding. That is, the hidden layer state of the current step is calculated by inputting the hidden layer state of the previous step and the output of the previous step, and then the output data of the next step is predicted. As the monitoring time increases, this method has the disadvantages, i.e., dramatic decrease of the prediction speed and sharp increase of the loss. By adopting the generative decoder, the prediction speed of the network may be quickened, and the propagation of accumulative errors during the deduction may be reduced.

Through the dynamic prediction mechanism, the digital twin model is ensured to reflect the state changes of the steel structure entity. Ultimately, such a configuration achieves the construction of the digital twin model well-coordinated and inter-connected with the steel structure entity. Thus, such a configuration enables operation and maintenance personnel to intuitively understand the global status of large-scale steel structures. In addition, the usability of the digital twin model is further improved by superimposing the identification result of the apparent damage obtained from inspection operations. This helps to transform the “passive maintenance” into “proactive maintenance,” thereby developing a new generation of intelligent safety operation and maintenance systems for large-scale steel structures.

Although the operations have been described in a particular order, this should be understood as requiring such operations to be performed in the particular order shown or in a sequential order, or understood that all the operations illustrated should be performed to achieve the desired result. Under certain circumstances, multitasking and parallel processing may be advantageous. Similarly, although several detailed implementation details are included in the foregoing discussion, these should not be construed as limiting the scope of the present application. Some features described in the context of separate examples may also be implemented in a way of combination in a single implementation. Conversely, various features described in the context of a single implementation may also be implemented individually or in any suitable way of sub-combination in multiple implementations.

Although the subject matter has been described using language specific to structural features and/or methodological acts, it should be understood that the scope of the present application is not necessarily limited to the specific features or acts described above. Rather, the specific features and acts described above are merely illustrative forms.

1. An intelligent operation and maintenance system for full life cycle of a large-scale steel structure, comprising a real-time data acquisition system, inspection equipment, and an integrated platform, wherein the integrated platform is configured to comprise:
a collaborative control module, configured to collaboratively control inspection equipment information, welding equipment, and repair equipment;
an equipment status monitoring module, configured to acquire real-time positioning of the inspection equipment, the welding equipment, and the repair equipment;
an intelligent identification and diagnosis module, configured to acquire an inspection image captured by the inspection equipment during an inspection process, and to perform damage identification and positioning on the inspection image based on a pre-trained damage identification model;
a digital twin model construction module, configured to construct a digital twin model and to perform online synchronization based on strain, temperature, or vibration distribution data acquired by the real-time data acquisition system; and
a digital twin model visualization module, configured to, in response to a visualization request, acquire a current digital twin model, and synchronize all of damage identified based on the inspection image, as well as information on the inspection equipment, the welding equipment, and the repair equipment in working conditions, to the digital twin model, and to perform visualization;
wherein the inspection equipment comprises an unmanned aerial vehicle (UAV) and a wall-climbing robot; and an inspection path planning method comprises:
acquiring three-dimensional (3D) point cloud data of the large-scale steel structure, determining a set of point clouds capable of falling within a field of view of the UAV according to a given flight altitude and a given field of view of the UAV, thereby obtaining an inspection range of the UAV; a set of point clouds beyond the inspection range of the UAV being an inspection range of the wall-climbing robot; planning inspection paths of the UAV and the wall-climbing robot within respective inspection ranges of the UAV and the wall-climbing robot; wherein, planning the inspection path of the UAV comprises:
extracting outer layer data according to the point cloud data within the inspection range of the UAV and expanding a set distance outward, and fitting to obtain an inspection flight plane of the UAV;
clustering the steel structure point cloud data within the inspection range of the UAV to obtain point cloud data of a plurality of steel segments, extracting a centerline according to the point cloud data of each steel segment to obtain a centerline spatial network; performing a 3D grid division on the centerline spatial network, and extracting a detection viewpoint for each grid traversed by a centerline;
for each detection viewpoint, calculating an intersection point where a distance to the inspection flight plane of the unmanned aerial vehicle from the detection viewpoint is minimized, clustering all the intersection points according to a set distance threshold to obtain a plurality of intersection point clusters, and taking a center of each intersection point cluster as a fixed inspection point position for the unmanned aerial vehicle;
the planning the inspection path for the wall-climbing robot within the inspection range of the wall-climbing robot comprises:
constructing a spatial coordinate system with a set position as an origin to obtain coordinate information of the point cloud data; and obtaining boundary coordinate information of the inspection range of the wall-climbing robot according to the inspection range of the wall-climbing robot;
dividing the steel structure point cloud data within the boundary range into steel segments, projecting all the steel segments onto a set two-dimensional (2D) plane, and calculating a projection matrix; extracting a detection viewpoint from each projected steel segment by grid sampling, and calculating line-of-sight (LOS) directions corresponding to all the detection viewpoints based on a plane normal vector feature; and
restoring all the viewpoints and the LOS directions to a 3D space according to the projection matrix, acquiring intersection points of all the LOS directions with a nearest steel segment, and determining steel segments where these intersection points are located; designating these steel segments as steel segments to be climbed, and designating these intersection points as fixed inspection point positions for the wall-climbing robot.

2. The intelligent operation and maintenance system for full life cycle of a large-scale steel structure according to claim 1, wherein a method for constructing the digital twin model comprises:
constructing an in-service steel structure geometric model based on multi-view point cloud data and a design drawing;
acquiring multi-source heterogeneous data reflecting a health status of the steel structure;
performing cross-modal fusion on the multi-source heterogeneous data to obtain a cross-modal fusion feature, specifically comprising:
obtaining a strain and temperature feature mapping and a vibration feature mapping based on the multi-source heterogeneous data of the steel structure;
calculating a characterization value of information of the strain and temperature feature mapping at any position as a univariate function;
calculating a correlation between the information of the strain and temperature feature mapping at any position and information of the vibration feature mapping at any position in a form of an embedded Gaussian function as a bivariate function;
performing cross-modal fusion based on the univariate function and the bivariate function to obtain a cross-modal fusion feature;
constructing the digital twin model corresponding to the in-service steel structure geometric model by combining in-service steel structure geometric model data with the cross-modal fusion feature data; and
performing dynamic prediction and correction on the constructed digital twin model to obtain a corrected digital twin model.

3. The intelligent operation and maintenance system for full life cycle of a large-scale steel structure according to claim 2, wherein a formula for the performing cross-modal fusion based on the univariate function and the bivariate function to obtain the cross-modal fusion feature is as follows:
$${y}_{i} = \frac{{\sum }_{∀ j} P ( {f}_{2 i} , {f}_{1 j} ) g ( {f}_{1 j} )}{{\sum }_{∀ j} P ( {f}_{2 i} , {f}_{1 j} )} ;$$
wherein, the univariate function g(·) serves to calculate the characterization value of the information f₁ⱼ of the feature mapping F₁ at position j; the bivariate function P serves to calculate the correlation between the information f₁ⱼ of feature mapping F₁ at position j and the information f₂ᵢ of feature mapping F₂ at position i in the form of an embedded Gaussian function.

4. The intelligent operation and maintenance system for full life cycle of a large-scale steel structure according to claim 2, wherein the constructing the digital twin model corresponding to the steel structure geometric model by combining steel structure geometric model data with the cross-modal fusion feature data comprises:
aligning the steel structure geometric model data and the cross-modal fusion feature data in both temporal and spatial dimensions;
training an inference model based on the aligned steel structure geometric model data and fusion feature data before and after parameter changing of the steel structure to obtain a trained inference model; and
in combination with real-time monitored multi-source heterogeneous data reflecting the health status of the steel structure and a finite element simulation analysis result, mapping the monitoring data to the 3D model by the trained inference model, to complete the construction of the digital twin model.

5. The intelligent operation and maintenance system for full life cycle of a large-scale steel structure according to claim 2, wherein the performing dynamic prediction and correction on the constructed digital twin model to obtain a corrected digital twin model is based on selecting different weights for multi-source data fusion according to differences in influences of multi-source data on different nodes, so as to achieve a purpose of minimizing a quadratic sum of Euclidean distances between a fusion result and each data.

6. The intelligent operation and maintenance system for full life cycle of a large-scale steel structure according to claim 1, wherein the operation and maintenance system further comprises a damage alarm module, configured to issue alarm information upon identifying damage, and the alarm information comprises a damage image and location information of a steel segment where the damage is located.

7. The intelligent operation and maintenance system for full life cycle of a large-scale steel structure according to claim 1, wherein the operation and maintenance system further comprises an intelligent repair module, configured to control a repair robot and a welding robot to autonomously repair the steel structure according to the location, type, and degree of the damage.
